(19) United States
(12) Patent Application Publication
(10) Pub. No.: US 2018/0374950 A1
(43) Pub. Date: Dec. 27, 2018

(54) SEMICONDUCTOR DEVICE AND METHOD OF MANUFACTURING THE SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Hitoshi KOBAYASHI, Hakusan Ishikawa (JP)

(21) Appl. No.: 15/910,448

(22) Filed: Mar. 2, 2018

(30) Foreign Application Priority Data
Jun. 23, 2017 (JP) 2017-123128

(51) Int. Cl. H01L 29/78; H01L 29/423; H01L 29/06; H01L 29/66; H01L 21/28

(52) U.S. Cl. CPC H01L 29/7827; H01L 29/4238; H01L 29/4236; H01L 21/28132; H01L 29/0696; H01L 29/66666; H01L 29/42376

(57) ABSTRACT

A semiconductor device includes a first electrode in a semiconductor layer, an insulating film on the semiconductor layer, covering the first electrode, a first pad on the insulating film, a second pad on the first insulating film, spaced from the first pad, and a contact through the first insulating film and electrically connecting the second pad to the first electrode. The first electrode has a first portion below the first pad and a second portion below the second pad. The first portion has recessed shape on its upper surface. The second portion has an upper surface in which any difference in height between its central portion and its adjacent end portions is less than the difference in height between a central portion of the first portion and the adjacent end portions of the first portion.

### CROSS-REFERENCE TO RELATED APPLICATION

This application is based upon and claims the benefit of priority from. Japanese Patent Application No. 2017-123128, filed Jun. 23, 2017, the entire contents of which are incorporated herein by reference.

### FIELD

Embodiments described herein relate generally to a semiconductor device and a method of manufacturing the same.

### BACKGROUND

A vertical MOSFET (Metal-Oxide-Semiconductor Field-Effect Transistor) having a drain pad on the lower surface of a semiconductor chip and a source pad and a gate pad on the upper surface the semiconductor chip has been developed. A technique for embedding a field plate electrode in the semiconductor chip to control the electric field distribution in the semiconductor chip of such a vertical MOSFET device has been proposed. In this case, each gate electrode is provided on a field plate electrode and is connected to a gate pad via a separate gate contact. However, as device feature sizes become finer in the planar dimension, it becomes difficult to reliably connect the contact to the gate electrode as required.

### DESCRIPTION OF THE DRAWINGS

FIG. 1 is a plan view showing a semiconductor device according to an embodiment.

FIG. 2A is a cross-sectional view taken along the line A-A′ in FIG. 1.

FIG. 2B is a cross-sectional view taken along the line B-B′ in FIG. 1.

FIG. 3 provides perspective views showing a gate electrode of the semiconductor device according to the embodiment.

FIGS. 4A and 4B are cross-sectional views depicting aspects of a method of manufacturing a semiconductor device according to an embodiment.

FIGS. 5A and 5B are cross-sectional views depicting aspects of a method of manufacturing a semiconductor device according to an embodiment.

FIG. 6 is a plan view depicting aspects of a method of manufacturing a semiconductor device according to an embodiment.

FIG. 7A is a cross-sectional view taken along the line A-A′ in FIG. 6.

FIG. 7B is a cross-sectional view taken along the line B-B′ in FIG. 6.

FIG. 8 is a cross-sectional view taken along the line C-C′ in FIG. 6.

FIGS. 9A and 9B are cross-sectional views depicting aspects of a method of manufacturing a semiconductor device according to an embodiment.

FIG. 10 is a cross-sectional view depicting aspects of a method of manufacturing a semiconductor device according to an embodiment.

FIGS. 11A and 11B are cross-sectional views depicting aspects of a method of manufacturing a semiconductor device according to an embodiment.

FIGS. 12A and 12B are cross-sectional views depicting aspects of a method of manufacturing a semiconductor device according to an embodiment.

FIGS. 13A and 13B are cross-sectional views depicting aspects of a method of manufacturing a semiconductor device according to an embodiment.

FIGS. 14A and 14B are cross-sectional views depicting aspects of a method of manufacturing a semiconductor device according to an embodiment.

FIGS. 15A and 15B are cross-sectional views depicting aspects of a method of manufacturing a semiconductor device according to an embodiment.

FIGS. 16A and 16B are cross-sectional views depicting a semiconductor device according to a comparative example.

### DETAILED DESCRIPTION

In general, according to one embodiment, a semiconductor device includes a semiconductor layer, a first electrode in the semiconductor layer, a first insulating film on a first surface of the semiconductor layer and covering the first electrode, a first pad on the first insulating film and electrically connected to the semiconductor layer, a second pad on the first insulating film and spaced from the first pad, and a contact through the first insulating film and electrically connecting the second pad to the first electrode. The first electrode comprises a first portion, below the first pad, and a second portion, below the second pad. An upper surface of this first portion has a recessed shape in which a central portion is farther from the first pad than are the adjacent end portions of the upper surface. The second portion has an upper surface in which any difference in height between a central portion and the adjacent end portions is less than any difference in height between the central portion of the upper surface of the first portion and the adjacent end portions of the central portion of the upper surface of the first portion.

A method of manufacturing the semiconductor device of the embodiment includes: forming a trench extending in a first direction in the upper portion of a semiconductor layer; forming a first insulating film on the inner surface of the trench and forming a first electrode member in a lower portion of the trench; forming a second insulating film in an upper portion of the trench; forming a first recess portion in an upper surface of the second insulating film in a first region; forming a second recess portion that is wider and deeper than the first recess portion in the upper surface of the first insulating film and the upper surface of the second insulating film in a second region located in the first direction when viewed from the first region; forming a third insulating film on an exposed surface of the semiconductor layer; forming a conductive film that buries the whole of the first recess portion and does not bury the whole of the second recess portion; forming a second electrode member in the first recess portion and on the inner surface of the second recess portion by selectively removing the conductive film; forming a fourth insulating film so as to cover the semiconductor layer and the second electrode member; and forming a contact connected to a portion formed in the first recess portion in the second electrode member in the fourth insulating film.

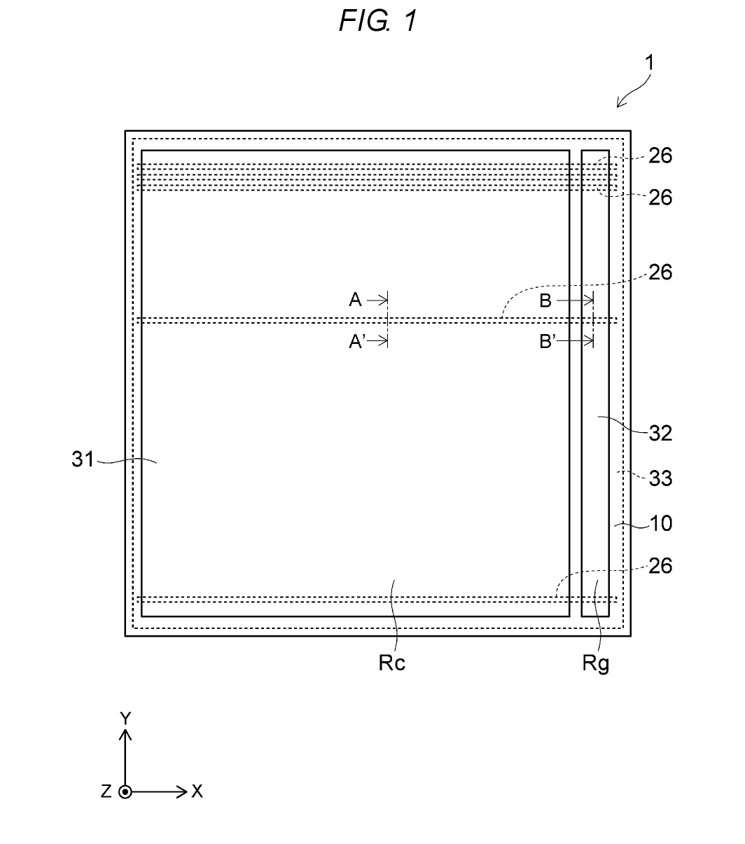

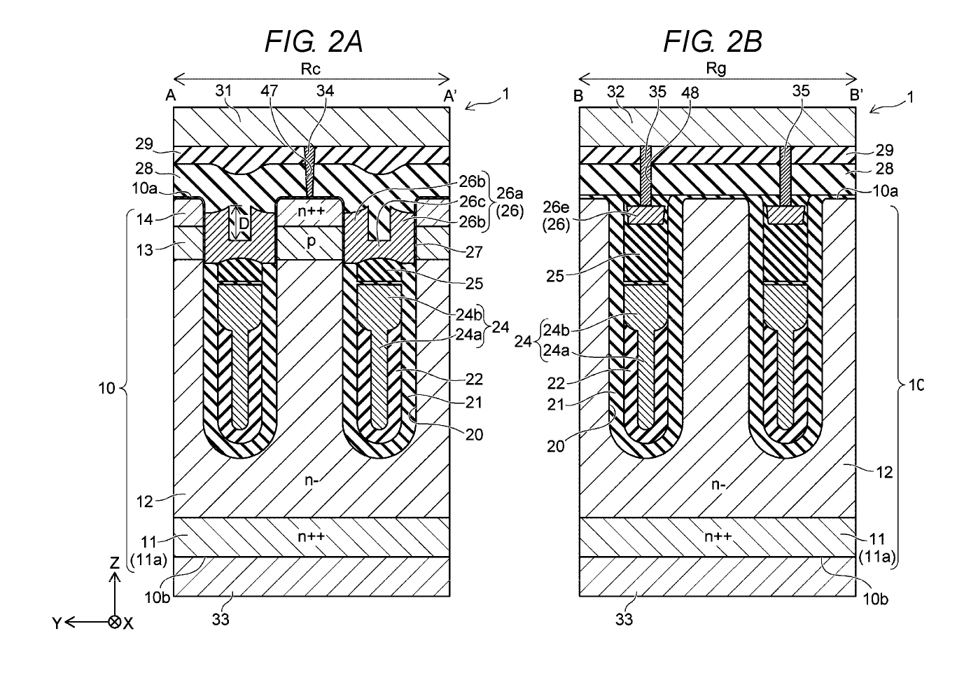

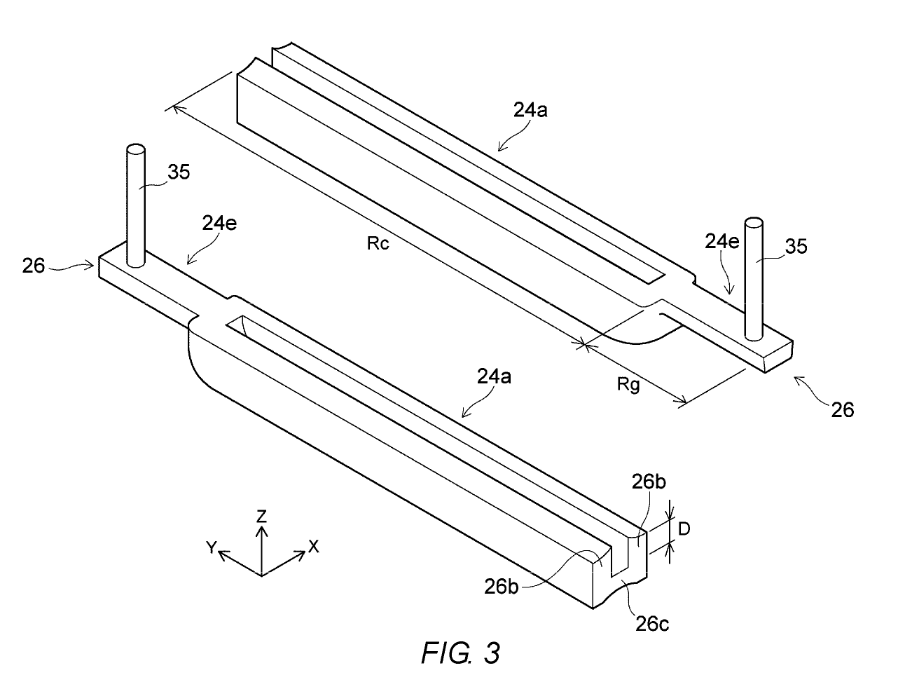

An example embodiment of the present disclosure will be described below with reference to the accompanying drawings. FIG. 1 is a plan view showing a semiconductor device according to the embodiment. FIG. 2A is a cross-sectional view taken along the line A-A′ shown in FIG. 1, and FIG. 2B is a cross-sectional view taken along the line B-B′ shown in FIG. 1. FIG. 3 provides perspective views showing a gate electrode of the semiconductor device from different directions.

It is noted that the respective drawings are schematic and some parts are exaggerated or omitted as appropriate for clarity of explanation. For example, in FIG. 1, only a few gate electrodes 26 are shown and several others are omitted. In addition, the number of components, the dimensional ratio and the like of components are not always coincident between the different drawings. The semiconductor device is, for example, a vertical power semiconductor device, such as a vertical MOSFET.

As shown in FIGS. 1, 2A and 2B, a silicon plate 10 is provided in a semiconductor device 1. As used herein, a “silicon plate” means a plate-like member or layer composed mainly of silicon (Si). The same applies to other component names. That is, when a material is included in the name of a component, the principal ingredient of that component is the named material thereof. Also, since silicon is generally a semiconductor material, a silicon plate is also a semiconductor plate or layer unless otherwise specified. The same also applies to other elements. Typically, in principle, the characteristics of a component reflect the characteristics of its principal compositional ingredient. The silicon plate 10 is made of, for example, single crystal silicon.

A source pad 31 and a gate pad 32 are provided so as to be separated from each other on an upper surface 10a of the silicon plate 10. The area of the source pad 31 is larger than the area of the gate pad 32. In addition, a drain pad 33 is provided on a lower surface 10b of the silicon plate 10. The source pad 31 and the gate pad 32 are made of, for example, a metal such as aluminum (Al). The drain pad 33 is made of, for example, a metal such as a titanium-nickel-gold (TiNiAu) alloy.

Hereinafter, for convenience of explanation, an XYZ orthogonal coordinate system is used herein. The thickness direction of the silicon plate 10 is defined as a “Z direction”, the arrangement direction (direction of spacing)of the source pad 31 and the gate pad 32 is defined as an “X direction”, and the direction orthogonal to the Z direction and the X direction is defined as a “Y direction”. In addition, the direction from the lower surface 10b to the upper surface 10a in the Z direction is also referred to as an “upper,” “upward”, “above,” or “higher” direction, and the opposite direction is also referred to as a “lower” or “below” direction, but such expressions are used primarily for convenience and are generally irrelevant with respect to device orientation with respect to the direction of gravity. When viewed from the Z direction, a region where the source pad 31 is provided is referred to as a cell region Rc, and a region where the gate pad 32 is provided is referred to as a gate region Rg. In the semiconductor device 1, a current flows mainly between the drain pad 33 and the source pad 31 in the cell region Rc.

In the silicon plate 10, a drain layer 11 of an n⁺⁺ type conductivity, a drift layer 12 of an n⁻ type conductivity, a base layer 13 of a p type conductivity, and a source layer 14 of an n⁺⁺ type conductivity are stacked in this order from the drain pad side. However, when viewed from the Z direction, the drain layer 11 and the drift layer 12 are disposed in both the cell region Rc and the gate region Rg, and the base layer 13 and the source layer 14 are disposed only in the cell region Rc.

The donor concentration of the drain layer 11 and the donor concentration of the source layer 14 are higher than the donor concentration of the drift layer 12. The drain layer 11, the drift layer 12, the base layer 13 and the source layer are integrally formed, and their boundaries are not necessarily distinct in all circumstances. The drain layer 11 constitutes the lower surface 10b of the silicon plate 10, and the source layer 14 constitutes the upper surface 10a of the silicon plate 10. The drain layer 11 is in contact with the drain pad 33 and electrically connected to the drain pad 33.

A plurality of trenches 20 extending lengthwise along the X direction are formed in the upper portion of the silicon plate 10. The trenches 20 are disposed across the cell region Rc and the gate region Rg. The lower end of each trench 20 is located in the drift layer 12. A silicon oxide film 21 is provided on the inner surface of a portion of the trench 20 located in the drift layer 12. A silicon oxide film 22 is provided on the lower side surface of the silicon oxide film 21.

A field plate (FP) electrode 24 made of a conductive material, such as polysilicon, is provided in the trench 20. A lower portion 24a of the FP electrode 24 is sandwiched between portions of the silicon oxide film 22, and an upper portion 24b is located higher than the silicon oxide film 22 and is in contact with the silicon oxide film 21 . Therefore, the width of the upper portion 24b (in the Y direction) is larger than the width (in the Y direction) of the lower portion 24a. The upper end of the FP electrode 24 is located lower than the upper end of the silicon oxide film 21. For example, the same potential as that of the source pad 31 is applied to the FP electrode 24.

A silicon oxide film 25 is provided above the FP electrode 24 at a position sandwiched between portions of the silicon oxide film 21. In the cell region Rc, the position of the upper end of the silicon oxide film 25 in the Z direction is substantially equal to the position of the upper end of the silicon oxide film 21, which is substantially equal to the position of the interface between the drift layer 12 and the base layer 13. On the other hand, in the gate region Rg, the position of the upper end of the silicon oxide film 21 is higher than the position of the upper end of the silicon oxide film 25.

Agate electrode 26 is provided on the silicon oxide film 25 in the trench 20. The gate electrode 26 is disposed in a region directly above the FP electrode 24 and extends in the X direction. The gate electrode 26 is integrally formed of a conductive material, for example, polysilicon.

As shown in FIGS. 2A and 2B and FIG. 3, the shape of a portion 26a of the gate electrode 26 disposed in the cell region Rc is different from the shape of a portion 26e disposed in the gate region Rg. Hereinafter, the shape of the gate electrode 26 will be described in greater detail.

A cross section (YZ plane cross section) orthogonal to the longitudinal direction (X direction) of the portion 26a has a recessed shape on an upper surface side. That is, the end portions 26b of the portion 26a spaced from each other the width direction (Y direction) protrude upward (Z-direction) along the inner surface of the trench 20 with respect to a central portion 26c. Therefore, the uppermost surface of an end portion 26b is located higher than the uppermost surface of the central portion 26c.

On the other hand, the cross section (YZ plane cross section) orthogonal to the longitudinal direction (X direction) of the portion 26e has a substantially rectangular shape. Therefore, the upper surface of the portion 26e is substantially flat. That is, any difference in the Z direction height between the ends of portion 26e in the width direction (Y direction) and its central portion (in the width direction) on the upper surface side is less than the difference D in the Z direction between the end portions (26b) and the central portion (26c) on the upper surface of the portion 26a. It is noted that the difference between the end portions of portion 26e and the central portion of the portion 26e is substantially zero in the example shown in FIG. 2B. In addition, the width (Y direction) of the portion 26e is narrower than the width (Y direction) of the portion 26a, and the thickness (Z direction) of the portion 26e is thinner than the maximum thickness (Z-direction) of the portion 26a. The upper surface of the portion 26e is located substantially at the same position as the upper end of the portion 26a in the Z direction, and the lower surface of the portion 26e is located higher than the lower surface of the portion 26a. Therefore, the portion of the silicon oxide film 25 disposed directly below the portion 26e is thicker than the portion of the silicon oxide film 25 disposed directly below the portion 26a.

In the cell region Rc, a gate insulating film 27 made of, for example, a silicon oxide is provided between the silicon plate 10 and the gate electrode 26. A silicon oxide film 28 is provided on the silicon plate 10, so as to cover the gate electrode 26. On the silicon oxide film 28, a BPSG (Boron Phosphorous Silicate Glass) film 29 is provided. The source pad 31 and the gate pad 32 are disposed on the BPSG film 29.

Contacts 34 and 35 extending in the Z direction are provided through the silicon oxide film 28 and the BPSG film 29. The lower end of the contact 34 is connected to the source layer 14, and the upper end thereof is connected to the source pad 31. The lower end of the contact 35 is connected to the upper surface of the portion 26e of the gate electrode 26 and the upper end of the contact 35 is connected to the lower surface of the gate pad 32. The contacts 34 and 35 are made of a metal such as tungsten (W).

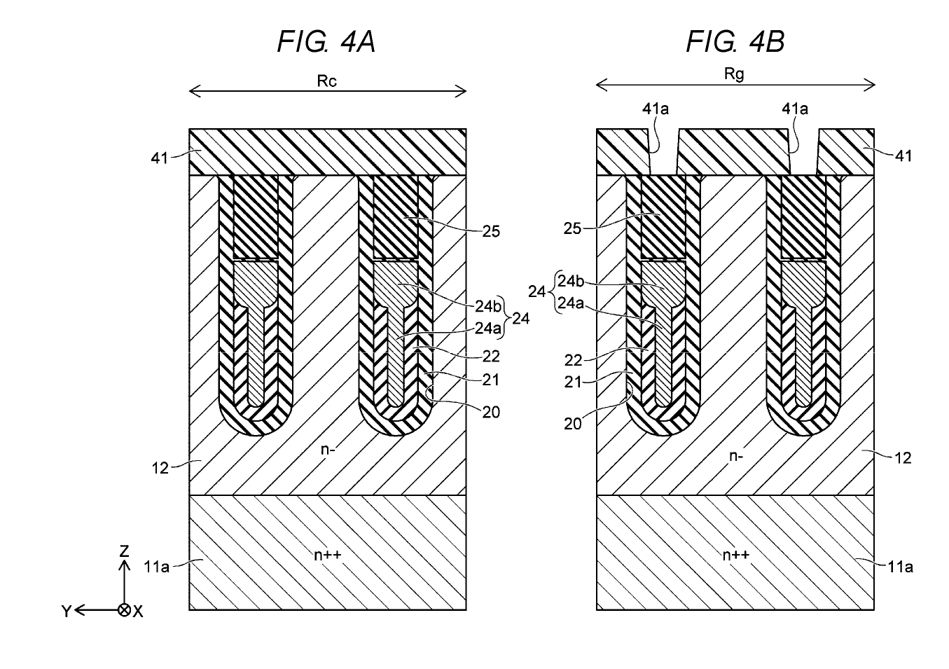

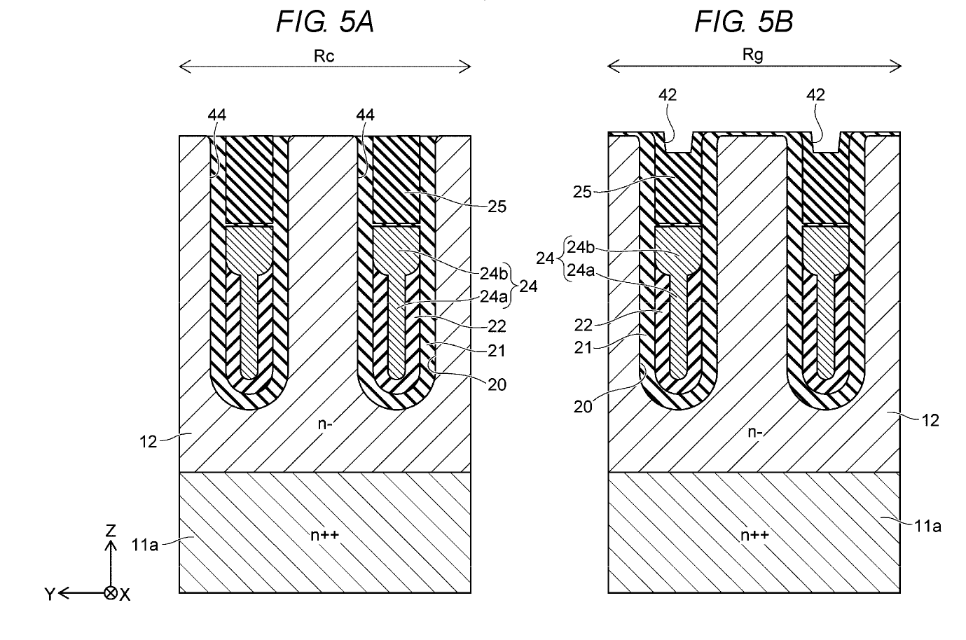

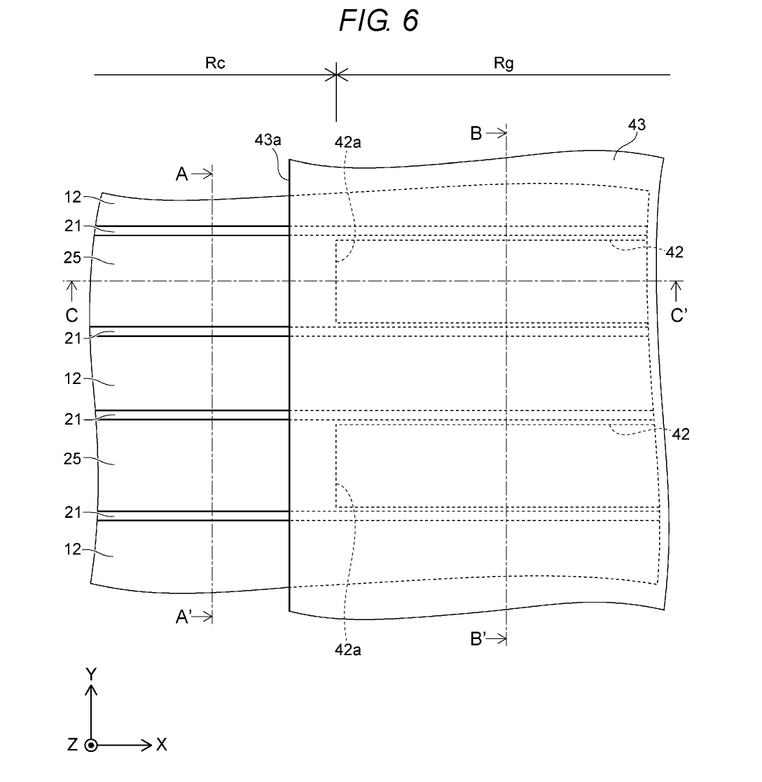

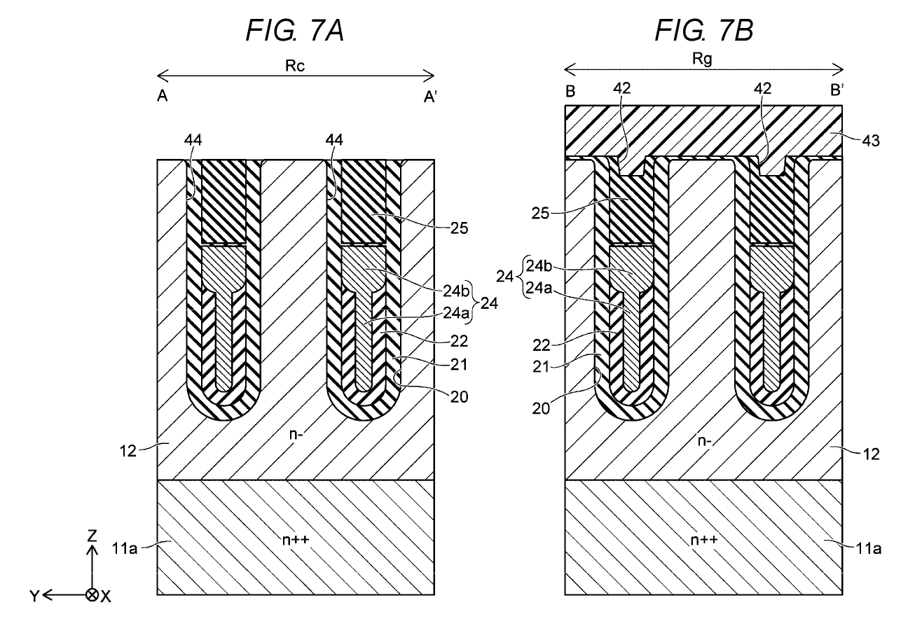

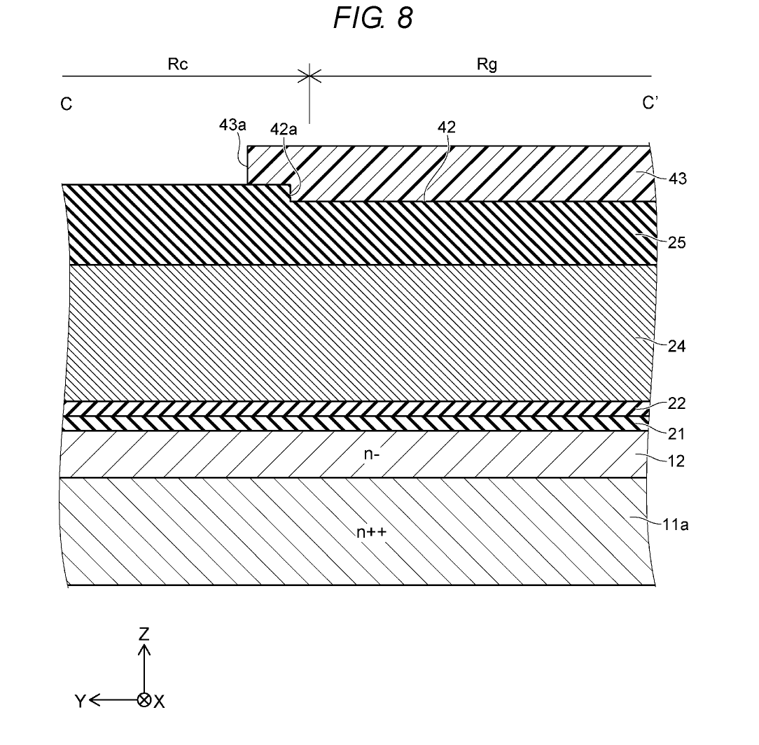

Next, a method for manufacturing the semiconductor device according to the embodiment will be described. FIGS. 4A and 4B and FIGS. 5A and 5B are cross-sectional views showing the method of manufacturing the semiconductor device according to the embodiment. The cross section shown in FIG. 4A corresponds to the cross section taken along the line A-A′ shown in FIG. 1, and the cross section shown in FIG. 4B corresponds to the cross section taken along the line B-B′ shown in FIG. 1. The same applies to FIGS. 5A to 5B. FIG. 6 is a plan view depicting aspects of the method of manufacturing the semiconductor device according to the embodiment. FIG. 7A is a cross-sectional view taken along the line A-A′ shown in FIG. 6, and FIG. 7B is a cross-sectional view taken along the line B-B′ shown in FIG. 6. FIG. 8 is a cross-sectional view taken along the line C-C′ shown in FIG. 6.

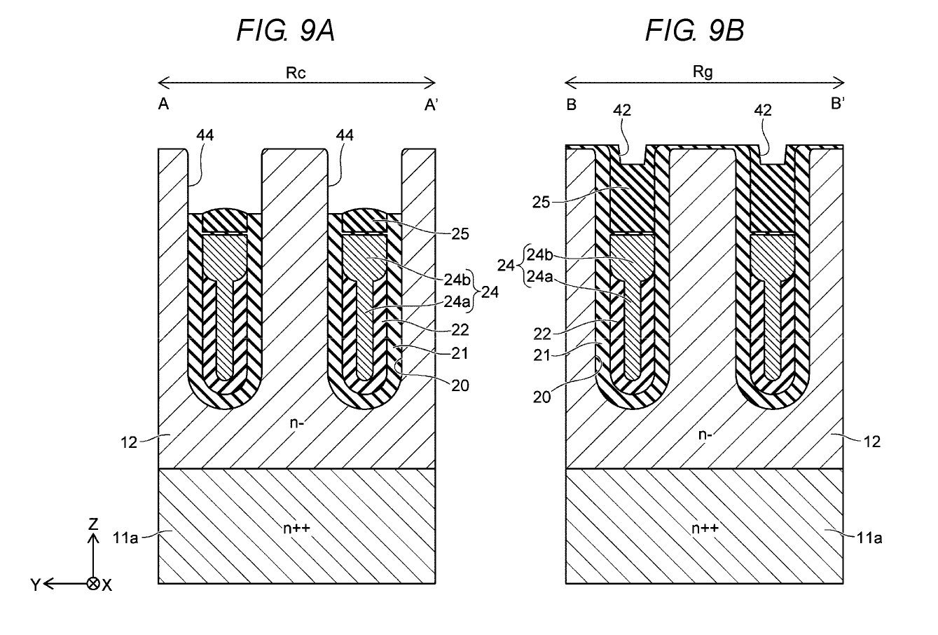

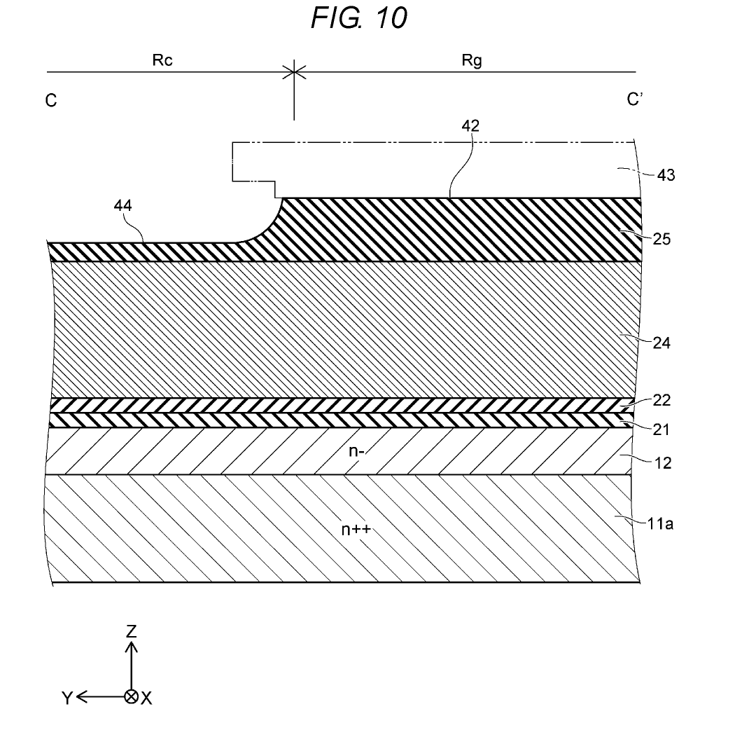

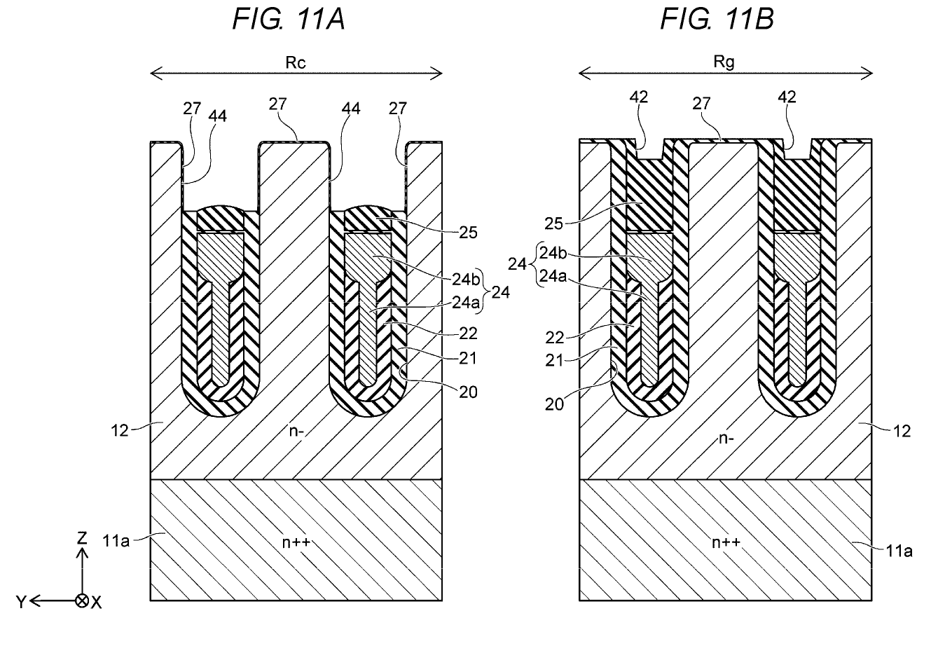

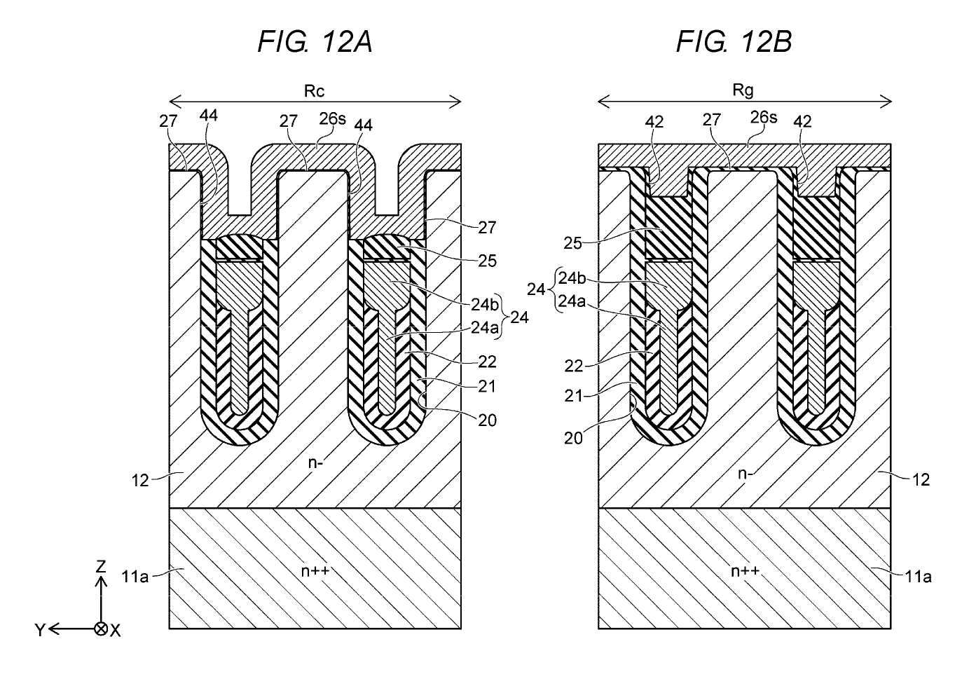

FIGS. 9A and 9B are cross-sectional views showing the method of manufacturing the semiconductor device according to the embodiment. The cross section shown in FIG. 9A corresponds to the cross section taken along the line A-A′ shown in FIG. 6, and the cross section shown in FIG. 9B corresponds to the cross section taken along the line B-B′ shown in FIG. 6. FIG. is a cross-sectional view showing the method of manufacturing the semiconductor device according to the embodiment. The cross section shown in FIG. 10 corresponds to the cross section taken along the line C-C′ shown in FIG. 6. FIGS. 11A and 11B to FIGS. 15A and 15B are cross-sectional views showing the method of manufacturing the semiconductor device according to the embodiment. The cross section shown in FIG. 11A corresponds to the cross section taken along the line A-A′ shown in FIG. 1, and the cross section shown in FIG. 11B corresponds to the cross section taken along the line B-B′ shown in FIG. 1. The same applies to FIG. 12A to FIG. 15B.

First, as shown in FIGS. 4A and 4B, a silicon substrate 11a is prepared. The silicon substrate 11a is a low resistance substrate, and contains, for example, phosphorus (P) , and has an n⁺⁺ conductivity type. Next, silicon is epitaxially grown on the upper surface of the silicon substrate 11a, thereby the drift layer 12 of an n⁻ type conductivity is formed. Next, a plurality of trenches 20 is formed in the upper portion of the drift layer 12. The trenches 20 extend into the drift layer form an upper surface side in the Z direction toward silicon substrate 11a. Each has a width in the Y direction and extends lengthwise in the Z direction.

Next, the silicon oxide film 21 is formed on the inner surface of each trench 20 by depositing a silicon oxide. Next, in the lower portion of the trench 20, the silicon oxide film 22 is formed on the surface of the silicon oxide film 21. Next, by depositing polysilicon, the FP electrode 24 is formed in the trench 20. A portion of the FP electrode 24 that is sandwiched between portions of the silicon oxide film 22 is the lower portion 24a and a portion that is disposed higher than the silicon oxide film 22 is the upper portion 24b. The upper portion 24b is wider than the lower portion 24a. Further, the upper surface of the FP electrode 24 is located lower than the upper surface of the drift layer 12.

Next, by depositing a silicon oxide, the silicon oxide film 25 is formed on the FP electrode 24 in the trench 20. Next, by performing dry etching, the silicon oxide deposited on the drift layer 12 is removed. Next, a resist mask 41 is formed on the drift layer 12, the silicon oxide film 21 and the silicon oxide film 25. In the resist mask 41, an opening 41a is formed in a region directly above the silicon oxide film 25 disposed in the gate region Rg.

Next, as shown in FIGS. 5A and 5B, using the resist mask 41 (see FIGS. 4A and 4B) as an etch mask, anisotropic etching, such as RIE (Reactive Ion Etching) , is performed. As a result, in the gate region Rg, a recess portion 42 is formed in the upper portion of the silicon oxide film 25. At this time, the silicon oxide film 21 is not etched. Next, the resist mask 41 is removed.

Next, as shown in FIG. 6, FIGS. 7A and 7B, and FIG. 8, a resist mask 43 is formed so as to cover the gate region Rg and expose the cell region Rc. An edge 43a of the resist mask 43 is disposed further into the cell region Rc than the edge 42a of the recess portion 42. The distance between the edge 43a and the edge 42a is set to be equal to or less than the iso-directional etching margin of the processes shown in FIGS. 9A and 9B, and FIG. 10, for example, 1 μm or less.

Next, as shown in FIGS. 9A and 9B, and FIG. 10, isotropic etching such as CDE (Chemical Dry Etching) is performed on the silicon oxide using the resist mask 43 as a mask. As a result, in the cell region Rc, a recess portion 44 is formed in the silicon oxide films 21 and 25. The recess portion 44 is formed to be deeper (in Z direction) than the recess portion 42. In addition, since the recess portion 44 is formed by removing both the silicon oxide films 21 and 25, it is wider (in Y direction) than the recess portion 42 formed by removing only the silicon oxide film 25. At this time, etching advances (undercuts) so as to go beyond the region directly below the resist mask 43, so that the recess portion 44 communicates with the recess portion 42. Next, the resist mask 43 is removed.

Next, as shown in FIGS. 11A and 11B, a thermal oxidation process is performed. Thereby, the gate insulating film 27 is formed on the exposed surface of the drift layer 12.

Next, as shown in FIGS. 12A and 12B, by depositing silicon by, for example, an LP-CVD (Low Pressure Chemical Vapor Deposition) method, a polysilicon film 26s is formed. The thickness of the polysilicon film 26s is set to such a thickness that the whole of the recess portion 42 is buried (filled) but the whole of the recess portion 44 is not buried (filled) .

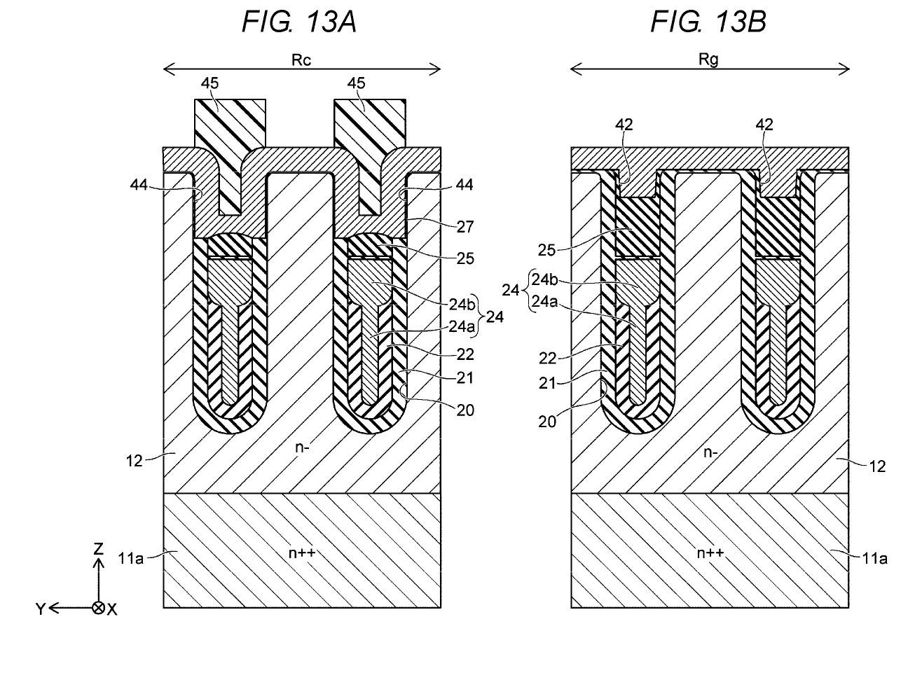

Next, as shown in FIGS. 13A and 13B, in the cell region Rc, a resist mask 45 is formed in a region directly above the recess portion 44. The resist mask 45 is not formed in the gate region Rg. Then, isotropic etching such as CDE is performed for removing silicon.

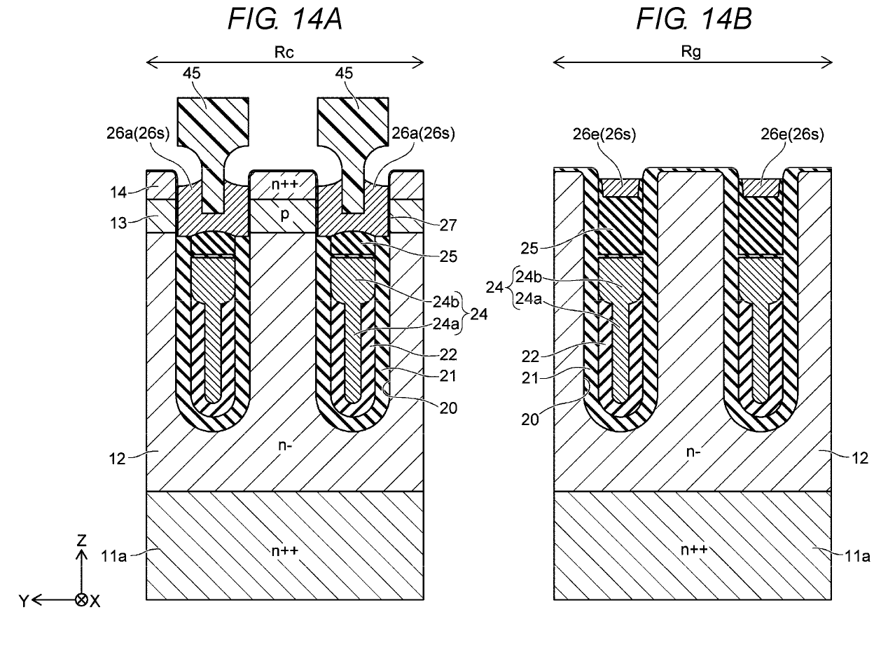

As a result, as shown in FIGS. 14A and 14B, in the cell region Rc, a portion of the polysilicon film 26s which was not covered with the resist mask 45 is removed, and also a portion of the polysilicon film 26s disposed directly below the resist mask 45 is also removed from the side, so that only some portion of the polysilicon film 26s deposited on the inner surface of the recess portion 44 remains. As a result, the portion 26a of the gate electrode 26 is formed from the polysilicon film 26s. On the other hand, in the gate region Rg, the polysilicon film 26s is uniformly etched back from the upper surface side, and the portion of the polysilicon film 26s disposed in the recess portion 42 remains. As a result, the portion 26e of the gate electrode 26 is formed from the polysilicon film 26s. The portions 26a and 26e form the gate electrode 26. Thereafter, the resist mask 45 is removed.

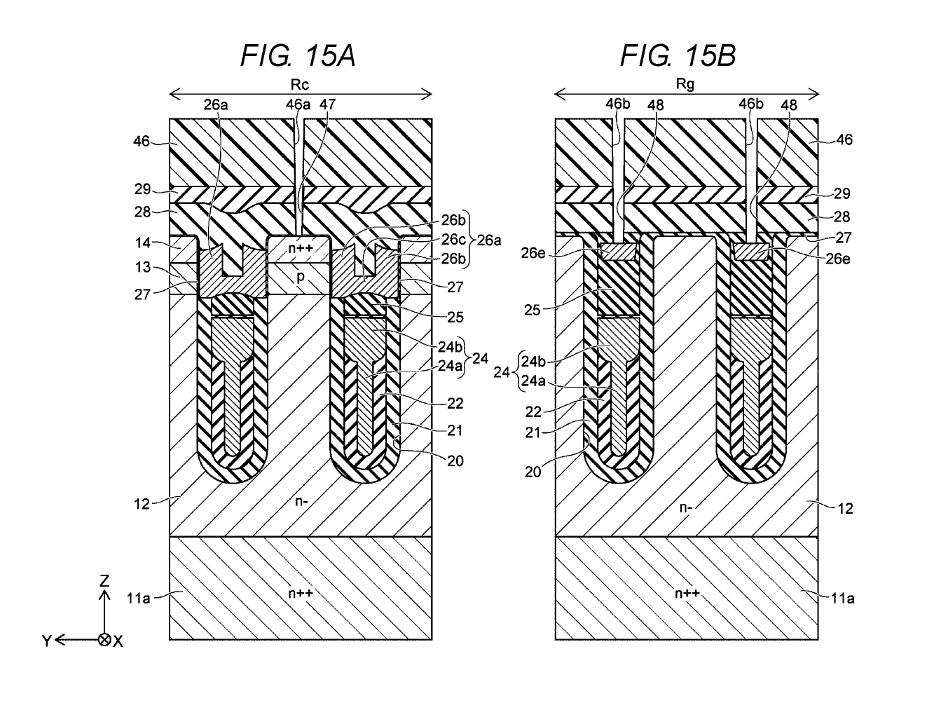

Next, as shown in FIGS. 15A and 15B, by implanting an impurity serving as an acceptor, for example, boron (B) in the cell region Rc, a p-type base layer 13 is formed on the top of the drift layer 12. Next, by implanting an impurity serving as a donor, for example, phosphorus (P) in the cell region Rc, an n⁺⁺ type source layer 14 is formed on the top of the base layer 13.

Next, the silicon oxide film 28 is formed on the entire surface by depositing an undoped silicon oxide. Unevenness reflecting the shape of the gate electrode 26 and the like is formed on the upper surface of this silicon oxide film 28 . Next, the BPSG film 29 is formed by depositing a silicon oxide containing boron and phosphorus. Unevenness reflecting the shape of the gate electrode 26 and the like is also formed on the upper surface of the BPSG film 29. Next, heat treatment at a temperature of, for example, 900° C. is performed to re-flow the BPSG film 29 so as to planarize the upper surface of the BPSG film 29. Next, a resist mask 46 is formed on the entire upper surface. In the resist mask 46, a hole 46a is formed in a region directly above the source layer 14 and a hole 46b is formed in a region directly above the portion 26e of the gate electrode 26.

Next, anisotropic etching, such as RIE, is performed. As a result, in the BPSG film 29 and the silicon oxide film 28, a contact hole 47 reaching the source layer 14 is formed in a region directly below the hole 46a and a contact hole 48 reaching the portion 26e of the gate electrode 26 is formed in a region directly below the hole 46b. Next, the resist mask 46 is removed.

Next, as shown in FIGS. 1, 2A and 2B, a metal such as tungsten is deposited and etch backed to form the contact 34 in the contact hole 47, and the contact 35 is formed in the hole 48.

Next, by depositing aluminum on the entire surface and performing patterning, the source pad 31 is formed in the cell region Rc and the gate pad 32 is formed in the gate region Rg. Next, the silicon substrate 11a is ground (polished) from the lower surface and thinned. Thereby, the silicon substrate 11a becomes the drain layer 11. Next, the drain pad 33 is formed on the lower surface of the drain layer 11 by, for example, sputtering. In this way, the semiconductor device 1 according to the embodiment can be manufactured.

Next, the effects of the example embodiment will be described. In this embodiment, the cross section of the portion 26a of the gate electrode 26 includes a recess shape. As a result, even if the trench 20 is formed to be thick, in the process shown in FIG. 12A, it is possible to form the gate electrode 26 having a necessary gate length without forming the polysilicon film 26s to be excessively thick.

As a result of the trench 20 being formed to be thick, it is possible to doubly form the silicon oxide films 21 and 22 in the trench 20, and change the distance between the FP electrode 24 and the drift layer 12 depending on the position in the Z direction. More specifically, the distance between the lower portion 24a of the FP electrode 24 and the drift layer 12 may be the total thickness of the silicon oxide films 21 and 22, and the distance between the upper portion 24b of the FP electrode 24 and the drift layer 12 may be equal to the thickness of the silicon oxide film 21. As a result, the electric field distribution in the silicon plate 10 can be precisely controlled, and, for example, electric field concentration can be relieved.

On the other hand, in the gate region Rg, the cross section of the portion 26e of the gate electrode 26 has a rectangular shape, and the upper surface of the portion 26e is flat. As a result, in the process shown in FIG. 15B, even if the position of the hole 46b of the resist mask 46 is somewhat shifted in the Y direction, the contact hole 48 does not necessarily miss the portion 26e, thus, the contact 35 can be reliably connected to the gate electrode 26. Therefore, the alignment margin of the hole 46b is relatively large, and the semiconductor device 1 can be more easily manufactured.

In addition, the recess portion 42 is formed in the gate region Rg in the process shown in FIG. 5B, the recess portion 44 which is deeper and wider than the recess portion 42 is formed in the cell region Rc in the process shown in FIG. 9B, the polysilicon film 26s is formed to have such a thickness the whole of the recess portion 42 is buried but the whole of the recess portion 44 is not buried in the process shown in FIGS. 12A and 12B, and the polysilicon film 26s is then isotropically etched in the process shown in FIGS. 14A and 14B. As a result, the gate electrode 26 shown in FIG. 3 can be formed.

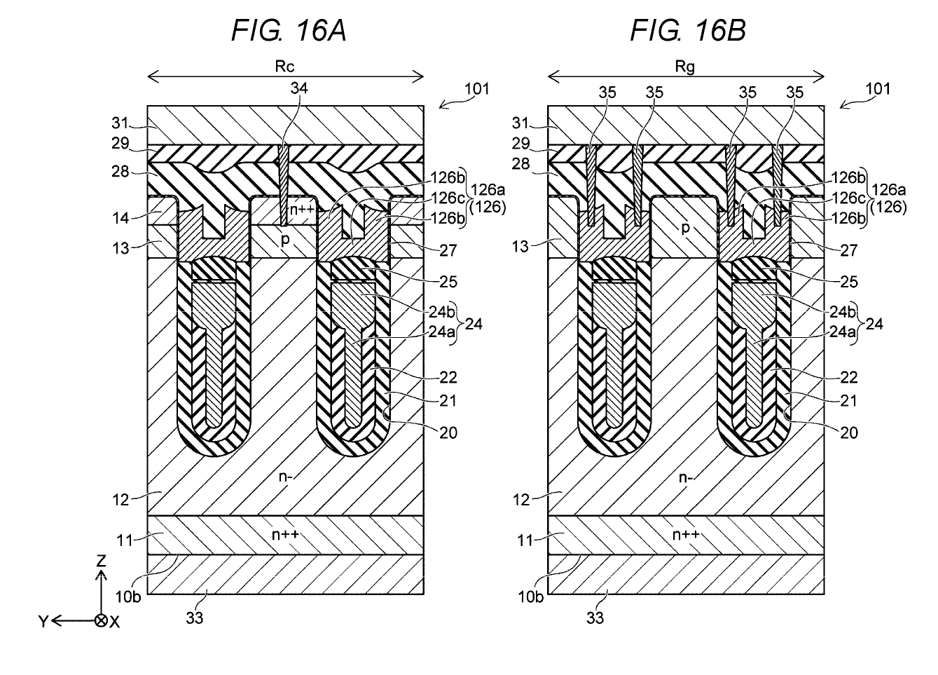

Next, a comparative example will be described. FIGS. 16A and 16B are cross-sectional views showing a semiconductor device according to a comparative example. As shown in FIGS. 16A and 16B, in the comparative example, without the process of forming the recess portion 42 as shown in FIGS. 4A and 4B and FIGS. 5A and 5B being performed, the recess portion 44 is also formed in the gate region Rg in the process shown in FIGS. 9A and 9B, and FIG. 10. Thus, in a semiconductor device 101 according to the comparative example, the cross section of a portion 126e disposed in the gate region Rg of a gate electrode 126 has a recess shape, similarly to the cross-sectional shape of a portion 126a disposed in the cell region Rc. Then, the contact 35 is connected to the upper surface of either end portion 126b of the portion 126e of the gate electrode 126.

In the comparative example, although it is necessary to make the contact 35 reach the upper surface at least one end portion 126b of the gate electrode 126 the width of either portion is narrow when compared to the width of the portion 26e of the gate electrode 26 in above-described embodiment, thus, the margin of alignment for the contact 35 in the Y direction is smaller. If the contact 35 is shifted toward the side of the central portion 126c of the gate electrode 126, which causes a shape defect, there is a possibility that the contact 35 will not be connected to the gate electrode 126. Further, if the contact 35 is shifted towards the outside of the gate electrode 126, there is a possibility that the contact 35 is short-circuited to the source layer 14. For this reason, when the semiconductor device 101 according to the comparative example is manufactured, it is necessary to precisely align the contact 35, which causes substantial difficulty in manufacture.

However, according to the example embodiment described above, it is possible to achieve a semiconductor device which is easier to manufacture than the comparative example by using the above-described method of manufacturing.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor layer;
a first electrode in the semiconductor layer;
a first insulating film on a first surface of the semiconductor layer and covering the first electrode;
a first pad on the first insulating film and electrically connected to the semiconductor layer;
a second pad on the first insulating film and spaced from the first pad; and
a contact through the first insulating film and electrically connecting the second pad to the first electrode, wherein
the first electrode includes:
a first portion below the first pad, and
a second portion below the second pad;
an upper surface of the first portion includes a recessed shape in which a central portion of upper surface is farther from the first pad than are end portions of the upper surface adjacent to the central portion; and
the second portion has an upper surface in which any difference in height between a central portion of the upper surface of the second portion and end portions of the upper surface of the second portion that are adjacent to the central portion is less than any difference in height between the central portion of the upper surface of the first portion and the end portions of the central portion of the upper surface of the first portion.

2. The semiconductor device according to claim 1, wherein a width, along a direction parallel to a plane of the semiconductor layer, of the second portion is smaller than a width, along the direction parallel to the plane of the semiconductor layer, of the first portion.

3. The semiconductor device according to 2, wherein a thickness, along a direction orthogonal to the plane of the semiconductor layer, of the second portion is less than a thickness, along the direction orthogonal to the plane of the semiconductor layer, of the first portion.

4. The semiconductor device according to 1, wherein a thickness, along a direction orthogonal to a plane of the semiconductor layer, of the second portion is less than a thickness, along the direction orthogonal to the plane of the semiconductor layer, of the first portion.

5. The semiconductor device according to claim 1, further comprising:
a third pad provided on a second surface of the semiconductor layer opposite the first surface, and
a second electrode between the first electrode and the third pad, the second electrode and having a width that is less than a width of the first portion of the first electrode.

6. The semiconductor device according to claim 5, wherein the second electrode includes:
a lower portion; and
an upper portion on the lower portion to be farther from the third pad than the lower portion, the upper portion having a width that is greater than a width of the lower portion.

7. A semiconductor device, comprising:
a semiconductor layer having a first surface side and a second surface side opposite the first surface side in a first direction;
a first insulating film on the first surface side of the semiconductor layer;
a first pad on the first insulating film, the first insulating film being between the semiconductor layer and the first pad in the first direction;
a second pad on the first insulating film, the first pad and the second pad being spaced from each other on the first insulating film in a second direction;
a source contact extending in the first direction through first insulating film and electrically connecting the first pad to a source region of the semiconductor layer; and
a first electrode in the semiconductor layer and including a first portion under the first pad in the first direction and a second portion under the second pad in the first direction, wherein
the first portion has a central portion that is at least a first distance from the first pad in the first direction and end portions spaced from each other across the central portion in a third direction orthogonal to the first direction, and the end portions are at least a second distance from the first pad in the first direction that is less than the first distance, and
the second portion is electrically connected to second pad, and the first portion is electrically connected to the second pad through the second portion, the second portion having an upper surface that is substantially flat.

8. The semiconductor device according to claim 7, wherein the first insulating film fills a recess formed between the end portions of the first portion of the first electrode.

9. The semiconductor device according to claim 7, wherein a gate contact extends in the first direction between from the upper surface of the second portion and the second pad.

10. The semiconductor device according to claim 7, further comprising:
a third pad disposed on the second surface side of the semiconductor layer; and
a field plate electrode between the first electrode and the third pad in the first direction.

11. The semiconductor device according to claim 10, wherein the field plate electrode includes:
a lower portion; and
an upper portion on the lower portion father from the third pad in the first direction than the lower portion.

12. The semiconductor device according to claim 7, wherein a width of the second portion in the third direction is less than a width of the first portion in the third direction.

13. The semiconductor device according to claim 7, wherein a thickness of the second portion in the first direction is less than a thickness of the first portion in the first direction.

14. The semiconductor device according to claim 7, wherein a distance from an uppermost surface of the first portion to the first pad in the first direction is greater than or equal to a distance from an uppermost surface of the second portion to the second pad in the first direction.

15. The semiconductor device according to claim 7, further comprising:
a base layer under the first pad in the first direction and adjacent to the first portion in the third direction.

16. A method of manufacturing a semiconductor device, comprising:
forming a trench into a semiconductor layer in a first direction, the trench extending lengthwise along a second direction crossing the first direction;
forming a first insulating film on an inner surface of the trench and forming a first electrode in a lower portion of the trench;
forming a second insulating film on an upper portion of the trench;
forming a first recess portion in an upper surface of the second insulating film in a first region of the semiconductor layer;
forming a second recess portion that is wider in a third direction crossing the second direction and deeper in the first direction than the first recess portion and the upper surface of the second insulating film in a second region of the semiconductor layer spaced from the first region in the first direction;
forming a third insulating film on an exposed surface of the semiconductor layer;
forming a conductive film that completely fills the first recess portion without completely filling the second recess portion;
forming a second electrode in the first recess portion and on the inner surface of the second recess portion by selectively removing portions of the conductive film;
forming a fourth insulating film covering the semiconductor layer and the second electrode; and
forming an electrical contact extending through the fourth insulating layer, the electrical contact connected to the connecting the second electrode.

17. The method according to claim 16, wherein forming the second electrode includes:
forming a mask covering a region directly above the trench in the second region in the first direction; and
performing isotropic etching with the mask on the conductive film under etch conditions which remove portions of the conductive film.

18. The method according to claim 16, further comprising:
forming a first and second conductive pad on the fourth insulating film, the second conductive pad being connected to the electrical contact formed in the fourth insulating film.

19. The method according to claim 18, wherein the second electrode includes:
a first portion below the first pad, and
a second portion below the second pad,
an upper surface of the first portion includes a recessed shape in which a central portion of upper surface is farther from the first pad than are end portions of the upper surface adjacent to the central portion, and
the second portion has an upper surface in which any difference in height between a central portion of the upper surface of the second portion and end portions of the upper surface of the second portion that are adjacent to the central portion is less than any difference in height between the central portion of the upper surface of the first portion and the end portions of the central portion of the upper surface of the first portion.

20. The method according to claim 19, wherein a width, along a direction parallel to a plane of the semiconductor layer, of the second portion is smaller than a width, along the direction parallel to the plane of the semiconductor layer, of the first portion.
